(19) United States
(12) Patent Application Publication
(10) Pub. No.: US 2003/0102878 A1
(43) Pub. Date: Jun. 5, 2003

(54) Bore probe card and method of testing

(76) Inventor: Thomas T. Montoya, Austin, TX (US)

Correspondence Address: SIMON, GALASSO & FRANTZ PLC., P.O. Box 26503, Austin, TX, 78755-0503, US

(21) Appl. No.: 10/281,071

(22) Filed: Oct. 24, 2002

Related U.S. Application Data
(60) Provisional application No. 60/367,365, filed on Oct. 24, 2001.

(51) Int. Cl. G01R 31/02

(52) U.S. Cl. 324/754

(57) ABSTRACT

A test apparatus using a bore probe card for testing a semiconductor die is disclosed. The bore probe card includes one or more bore probes that operate to bore into the bond pads of the semiconductor die without laterally scrubbing across the surface of the bond pad. The bore probes generally contact the bond pads at approximately 90° and a lateral pattern between the bore probe card and the semiconductor die produces the boring action of the bore probes.

### CROSS REFERENCE TO RELATED APPLICATIONS

This application claims the benefit of U.S. Provisional Patent Application Serial No. 60/367,365, filed Oct. 24, 2001, entitled “Bore Probe Card And Method Of Testing.”

### TECHNICAL FIELD OF THE INVENTION

This invention relates in general to the field of electronic systems, and more particularly to semiconductor device testing systems and methods.

### BACKGROUND OF THE INVENTION

Semiconductor devices, i.e., integrated circuits, are used in nearly all electronic systems, from the simple, such as televisions, watches, blenders, and the like; to the complex, such as computers, air-bag safety systems, personal digital assistants (PDA's), medical testing systems, communication systems, and the like. Semiconductor devices are produced by a complex fabrication process that forms minute electrical circuits within a semiconductor material, such as silicon and gallium arsinide. As the size, or pitch, of the electrical circuits decrease, the density of electrical circuits within a semiconductor device correspondingly increase. In general, the greater the density of electrical circuits, the greater the operating speed and functionality of the semiconductor device and the lower the power requirements.

As semiconductor devices increase in complexity and density, testing becomes increasingly difficult and expensive. During the fabrication process, semiconductor devices, or dies, are individually tested at the wafer level to detect imperfections prior to being cut from the wafer and packaged as an integrated circuit. A test system applies and measures electronic signals from the die. Based on the electronic signals, the die is sorted for failure and for grade. Die that fail are discarded, whereas acceptable die vary by performance, with high performing die's commanding a higher price than lower performing die's. Testing at the wafer level also reduces costs by detecting flaws in the die prior to the packaging process.

Each die includes multiple bond pads that form the electrical contacts between the electrical circuits within the die and the outside world. The bond pads are fabricated from a conductive metal, such as aluminum or copper. When exposed to air, the conductive metal oxidizes and forms a thin abrasive nonconductive oxide layer on the surface of the bond pad. In order to test the die or couple conductive pins to the die, a good electrical contact must be made with the conductive metal under the oxide surface layer.

Conventional test systems generally utilize a probe card that includes individual probes for contacting individual bond pads of one or more die. Conventional probes for testing small size bond pads (under 150 microns) are generally of the scrub probe type. Scrub probes contact the surface of the bond pad at an angle. The contact surface of each probe is planarized to be parallel to the surface of the bond pad. This allows all the probes to contact the bond pads at the same instant. Upon contact, the wafer is moved into an overdrive position. The angle of the probe forces the contact surface to scrape, or scrub, across the surface of the bond pad. The scrubbing action pushes the heel of the contact surface through the oxide layer into the conductive region of the bond pad to produce a good electrical contact, i.e., low electrical resistance, between the scrub probe and the bond pad. In contrast, a poor electrical contact, i.e., high electrical resistance, negatively affects the tested performance of the die, which can result in the die failing the test or being downgraded.

One disadvantage of conventional testing procedures is that the bond pad must have a certain minimum size to allow the probe to laterally scrub across the bond pad. The length and width of the bond pad cannot be reduced below a certain minimum size due to the required lateral motion of the probe across the bond pad. For example, conventional testing techniques cannot easily test bond pads having a pitch less than 40 microns. As a result, the size of the die is larger than could otherwise be manufactured. Accordingly, fewer die can be fabricated on a semiconductor wafer than could otherwise be fabricated. In addition, larger die generally have lower processing speeds and produce more heat than smaller die. A further restraint is the thickness of the bond pad. Conventional testing requires a minimum bond pad thickness to protect the delicate electrical circuits under the bond pad from the scrubbing action of the probe (approximately 0.1 microns).

Another disadvantage is that the contact resistance of conventional scrub probes increase each time the probe scrubs through the oxide layer of the bond pad. Conventional scrub probe cards generally last on the order of 200,000-500,000 touchdowns, with repair and cleaning generally required when the contact resistance reaches a set value in ohms, which is generally on the order of every 20-30,000 touchdowns. As used in the art, a touchdown, or cycle, refers to contact between the probes and the bond pads. For example, a probe card that tests five die simultaneously will require six touchdowns to test a wafer having thirty die. In this example, if each die is tested twice, twelve touchdowns are required to test the wafer.

Conventional probe cards are often repaired by simultaneously lapping or polishing the probes on a media of ceramic or diamond girt. This changes the shape of the probe, i.e., the heel of the probe. Although the probe card may be able to be repaired and cleaned multiple times, repair is time consuming and it is expensive to remove, replace, and align the probes card. In addition, if any of the probes are damaged such that they are out of alignment, the probe card must be repaired by hand or discarded.

As the probes wear, the ability of the probes to effectively scrub through the oxide layer and make a good electrical contact with the conductive region of the bond pads is reduced. As a result, otherwise acceptable dies are rejected or downgraded, thereby reducing efficiency and increasing fabrication costs. In addition to the probe wearing, the contact surface of the probe can become fouled with debris. The debris increases the electrical contact resistance between the probe and the bond pad, which negatively affects accurate testing and the performance of the die. Each of these problems can produce false negative errors during the testing process.

### SUMMARY OF THE INVENTION

One implementation of the present invention comprises a bore probe card. In one embodiment, the bore probe card comprises a base and a plurality of bore probes coupled to the base. Each bore probe operates to bore into a bond pad of a semiconductor die in response to a lateral pattern of the semiconductor die relative to the base. The lateral pattern facilitates the boring action that allows the bore probe to penetrate into the bond pad. Each bore probe generally comprises a spring and a needle. In this embodiment, the needle operates to contact the bond pad at a contact angle between the needle and the surface of the bond pad that substantially prevents the needle from laterally scrubbing across the bond pad.

Another implementation of the present invention comprises a test apparatus for testing a semiconductor die. In one embodiment, the test apparatus comprises a bore probe card, a wafer handling system, and a tester. The bore probe card includes a plurality of bore probes that operate to contact bond pads of the semiconductor die without substantially scrubbing laterally across the bond pad. The wafer handling system operates to move the wafer into overdrive and in a lateral pattern while the die is engaged with the bore probe card. The tester then operates to test the die while the bore probes contact the bond pads.

Another implementation of the present invention comprises a method for fabricating a device. In one embodiment, the method includes providing a wafer having a plurality of semiconductor die, wherein each semiconductor die includes a plurality of bond pads. Each semiconductor die is then tested in the wafer using a bore probe card having bore probes that bore into the bond pads of the semiconductor die without substantially scrubbing across the bond pads. Each semiconductor die is then cut from the wafer. A pin is then bonded to at least one of the bond pads of the die. The semiconductor die is then encapsulated within a protective material.

Yet another implementation of the present invention comprises a method of fabricating a bore probe card. In one embodiment, the method comprises positioning a plurality of bore probes to align with a respective bond pad on a semiconductor die. The plurality of bore probes are then secured within a base. The bore probes are then planarized to produce a planarized probe tip. A shaped probe tip is then formed from the planarized probe tip.

The present invention provides certain technical advantages over conventional systems and methods. Particular implementations and embodiments of the present invention may have all, some, or none of these technical advantages. For example, in some embodiments, the boring action of the bore probes may produce a relatively small contact area as compared to conventional probes. In one embodiment, the size of the contact area produced by the bore probe was approximately 0.4 microns in depth by 0.8 microns diameter, whereas a conventional scrub probe creates a contact area of approximately size of probe tip wide i.e., 0.02 microns by 50 microns long by 0.05 microns deep. This allows bond pads having a length and/or width of less than 40 microns to be tested. Accordingly, the die can be fabricated smaller without sacrificing the number of bond pads on the die. As a result, the number of die per wafer can be increased and the circuit density can be increased, thereby improving die operating performance and reducing the heat generated by the die. The same size die could be fabricated with a greater number of bond pads for testing or communication.

Some embodiments of the bore probe card have a higher operational life than conventional probe cards. In particular, one embodiment of a bore probe card has been tested to over 1.5 million touchdowns without showing any wear or degradation in operating parameters, such as contact resistance. The higher operational life reduces the number of probe cards required for testing a specific number of die. It also reduces the time the test apparatus is inoperable due to repair or replacement of the probe card. Accordingly, testing costs are reduced.

The present invention may reduce the occurrence of false negative test results as compared to conventional testing methods. In other words, conventional testing method often reject otherwise acceptable die because of problems in the testing process. By reducing the occurrence of false negative test results, more accurate tests are completed and a higher yield of acceptable and high-grade die are produced.

Other advantages will be readily apparent to one skilled in the art from the following figures, descriptions, and claims.

### BRIEF DESCRIPTION OF THE DRAWINGS

For a more complete understanding of the present invention and for further features and advantages thereof, reference is now made to the following description taken in conjunction with the accompanying drawings, wherein like reference numerals represent like features, in which:

FIG. 1A is a top view illustrating one embodiment of a wafer having multiple die fabricated in the wafer in accordance with the present invention;

FIG. 1B is a cross sectional side view, in part, illustrating a die taken along line 1B-1B shown in FIG. 1A in accordance with the present invention;

FIG. 1C is a perspective view illustrating one embodiment of an electronic system having an electronic device in accordance with the present invention;

FIG. 2A is a side view illustrating one embodiment of a test apparatus for testing the wafer shown in FIG. 1A using one embodiment a bore probe card in accordance with the present invention;

FIG. 2B is a flow chart illustrating the operation of the test apparatus of FIG. 2A in accordance with the present invention;

FIGS. 3A-3C are a side views illustrating the operation of prior art scrub probes;

FIGS. 4A-4D are side views illustrating the operation of the bore probes of FIG. 2A in accordance with the present invention;

FIG. 4E is a graph illustrating contact resistance of a bore probe as a function of touchdowns in accordance with the present invention;

FIGS. 5A-5F are top views illustrating various embodiments of a lateral pattern in accordance with the present invention;

FIGS. 6A-6C are side views illustrating various embodiments of a shaped probe tip in accordance with the present invention;

FIGS. 7A-7C are side views illustrating various embodiments of the bore probe card of FIG. 2A in accordance with the present invention; and

FIG. 8 is a flow chart illustrating the fabrication of the bore probe card of FIG. 2A in accordance with the present invention.

### DETAILED DESCRIPTION OF THE INVENTION

This application discloses a number of inventions relating to semiconductor device fabrication and testing. This application describes the inventions in terms of a test apparatus for testing semiconductor die at the wafer level. It should be understood that the individual inventions may be used individually, in any combination, or in total, depending upon the implementation. In addition, the inventions may also be used in other semiconductor testing applications, semiconductor fabrication processes, and processes not directly relating to semiconductors.

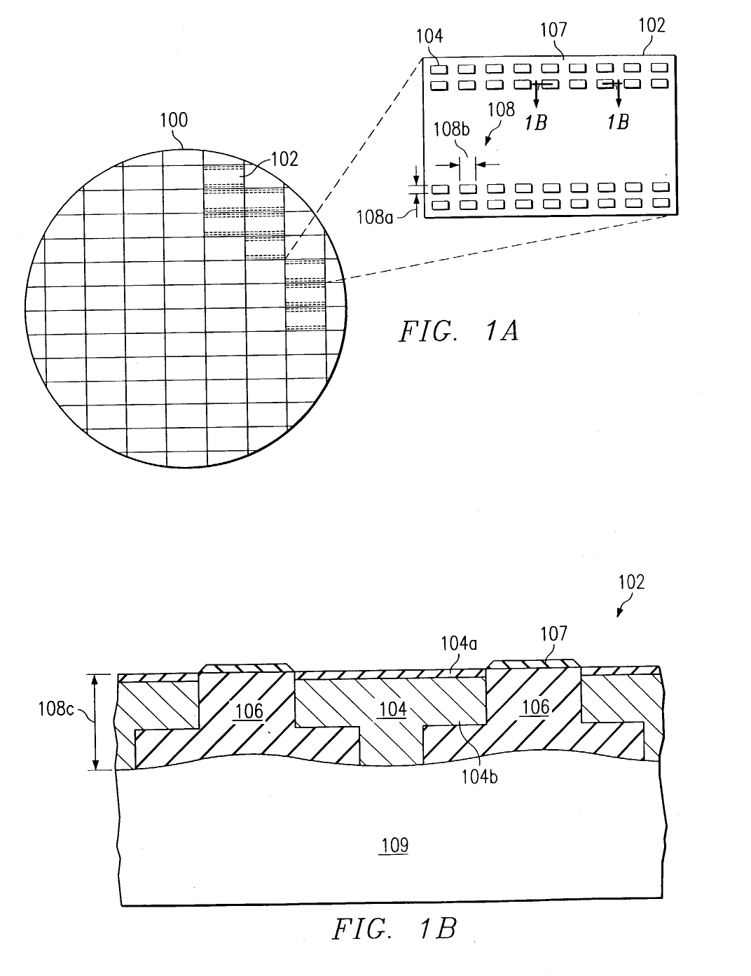

FIG. 1A illustrates a top view of the surface of a wafer 100 having multiple die 102 formed in wafer 100. Each die 102 includes electrically conductive bond pads 104 surrounded by dielectric material 106 covered by a passivation layer 107. Each bond pad 104 forms a point of electrical contact between the sensitive electrical circuits (shown in FIG. 1B) within the die 102 and the outside world. The bond pads 104 may comprise any suitable conductive material, such as aluminum, copper, gold, and the like, and comprise any suitable configuration, such as, flat bond pads, peripheral bump pads, array bump pads, and the like. Each bond pad 104 has a certain size 108 (length 108a, width 108b, and thickness 108c). In general, the smaller the length 108a and/or width 108b, the smaller corresponding size of the die 102, and the greater the number of die 102 that can be formed on the wafer 100. The minimum length 108a, width 108b, and thickness 108c (shown in FIG. 1B) of the bond pad 104 is often limited by the testing method. In particular, conventional fabrication processes allow the production of smaller and thinner bond pads 104, but conventional testing methods to not allow for testing of these smaller bond pads 104. As described in greater detail below, one embodiment of the present invention allows the minimum length 108a, width 108b, and thickness 108c of the bond pad 104 to be reduced as compared to the size 108 required for conventional testing methods.

FIG. 1B is a cross-section side view of a portion of a die 102 showing bond pads 104 and electrical circuits 109. As discussed above, bond pads 104 are fabricated from an electrically conductive material. During the testing process, the wafer 100 is exposed to air, which oxidizes the conductive material of the bond pad 104 and produces a hard thin non-conductive oxide layer 104a on the surface of a conductive region 104b. In order to accurately test the operation of the electrical circuits 109, extremely accurate power and logic voltages must be applied and measured at the conductive region 104b of the bond pad 104. Accordingly, the oxide layer 104a must be removed or otherwise penetrated in order to provide a low resistance electrical contact between the testing apparatus and the conductive region 104b of the bond pad 104.

FIG. 1C is a perspective view, in part, of an electronic system 114, having an electronic device 110 shown in cross-section. The electronic device 110 includes die 102 that has been tested in accordance with the testing process as described in detail below. The die 102 is then cut from the wafer 100 and packaged as the electronic device 110. The packaging process generally involves attaching an electrically conductive pin 112 to each bond pad 104 and then encapsulating the die 102 in a protective material, such as plastic, to protect the die 102. The pins 112 form conductive links that operate to electrically couple the die 102 to the electronic system 114, such as a computer, digital watch, circuit board, and the like. In the embodiment illustrated, the pins 112 extend outward in a pattern that allows the electronic device 110 to be plugged into a matching socket 116 in the electronic system 114. In other embodiments, the pins 112 are solder links that permanently attach the electronic device 110 to a circuit board within the electronic system 114.

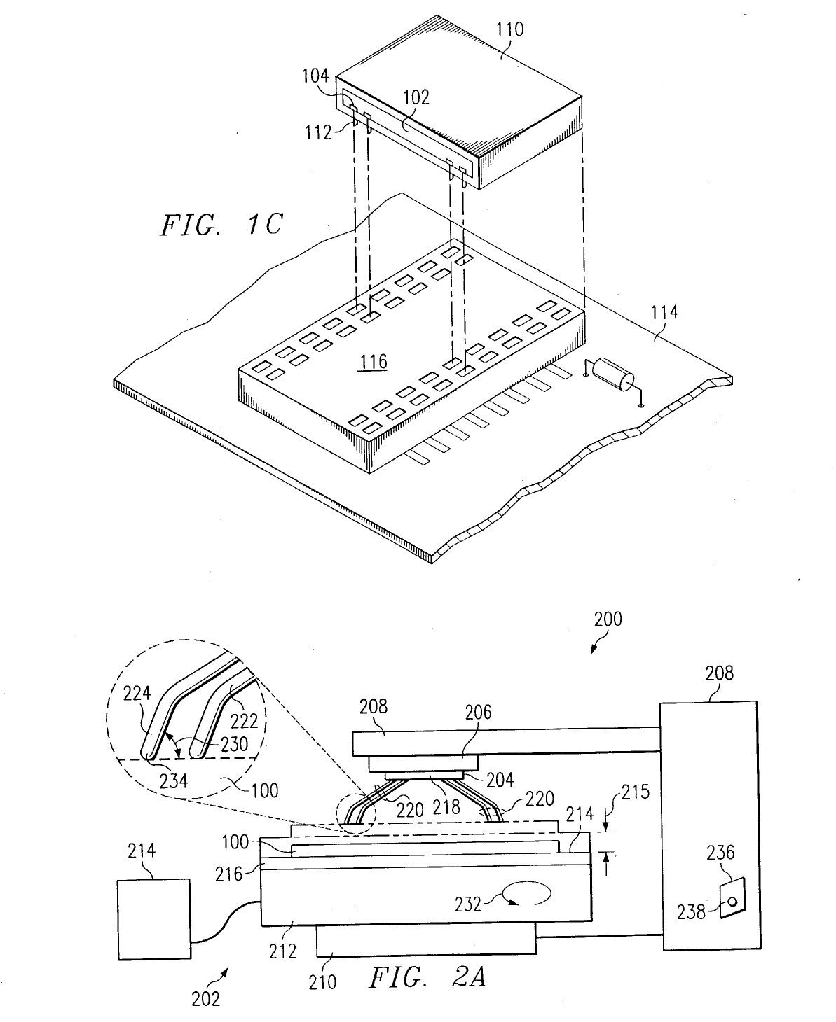

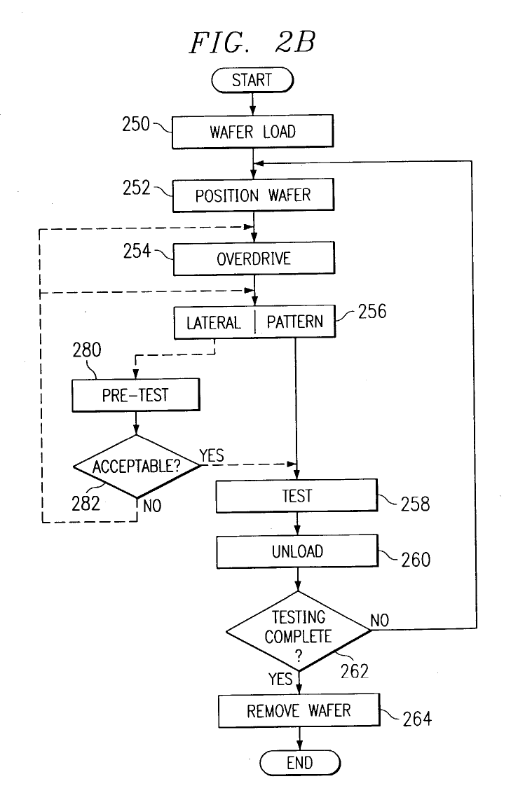

FIG. 2A is a side view of one embodiment of a test apparatus 200 for testing the die 102 in the wafer 100. In this embodiment, the test apparatus 200 comprises a wafer handling system 202, a bore probe card 204, a test head 206, and a tester 208. The wafer handling system 202 provides a movable mounting surface for the wafer 100. The wafer handling system 202 generally includes a positioning system 210 and a chuck 212. The positioning system 210 operates to accurately position and move the chuck 212 in three dimensions. As illustrated, the X-axis and Y-axis define a plane parallel to a mounting surface 214 of the chuck 212, and the Z-axis is perpendicular to the plane formed by the X-Y axis. Movement in the Z-axis moves the chuck 212, and thus the wafer 100, vertically into or out-of engagement with the bore probe card 204. The position, or distance, of Z-axis engagement between the wafer 100 and the bore probe card 204 is referred to overdrive 215. The greater the overdrive 215, the greater the compression, or gram-force, applied by the bore probe card 204 to the bond pads 104 of the die 102.

The chuck 212 provides a flat and rigid mounting surface 214 for securing the wafer 100 onto the chuck 212. The chuck 212 generally includes a plate 216 that forms the mounting surface 214 for the wafer 100. In the preferred embodiment, the plate 216 is fabricated from a crystalline material having a low porosity. In one embodiment, the crystalline material is a natural stone material, such as granite, marble, and the like. In another embodiment, the plate 216 is coated with a crystalline material, such as diamond, quartz, and the like. In this embodiment, the coated crystalline material allows the plate 216 to be heated or cooled relatively quickly. The crystalline material allows the mounting surface 214 of the plate 216 to have flatness of 1 micron or less. Conventional chucks are generally fabricated from stainless steel and have a flatness equal to 127 microns or more. Improving the flatness of the mounting surface 214, i.e., making the mounting surface 214 flatter, reduces variations in the Z-axis height of the wafer 100 when mounted on the chuck 212. As a result, the bore probe card 204 evenly engages the bond pads 104 of the wafer 100 at substantially the same time. Thereby improving the engagement, i.e., consistent electrical connection, between the probe card 204 and the wafer 100. The crystalline material of the plate 215 also reduces the negative effects of thermal variations during testing. In many cases, the wafer 100 is hot tested. Hot testing heats the chuck 212 and wafer 100 while the wafer 100 is being tested. Conventional metallic chucks have high coefficients of expansion and can warp during the hot test, thereby causing improper alignment of the bore probe card 204. In contrast, the plate 216 fabricated from the crystalline material will not warp or be substantially affected by hot testing the wafer 100.

The wafer handling system 202 may also includes a vacuum system 217 for securing the wafer 100 to the chuck 212. In the embodiment illustrated, the chuck 212 includes orifices (not expressly shown) that communicate a vacuum pressure i.e., pressure below atmospheric pressure, to the interface between the wafer 100 and the chuck 212. The pressure differential between the vacuum pressure and the atmospheric pressure acting on the wafer 100 secures the wafer 100 onto the mounting surface 216 of the chuck 212.

The bore probe card 204 operates to make electrical contact with the bond pads 104 of one or more die 102. The bore probe card 204 includes a base 218 and bore probes 220. The base 218 secures the alignment of the bore probes 220 and provides a standardized plug for electrically connecting the bore probes 220 to the test head 206. The bore probes 220 extend from the base 218 in a pattern that allows each bore probe 220 to simultaneously contact the bond pads 104 of one or more die 102.

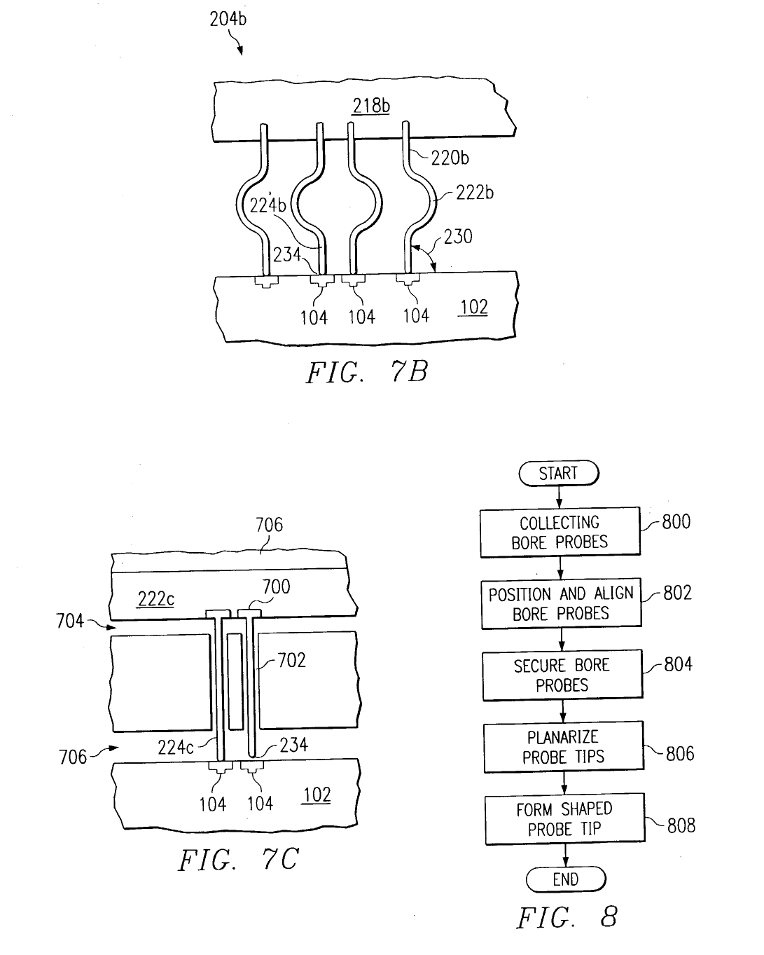

Each bore probe 220 includes a spring 222 and a needle 224. The spring 222 operates to apply a load, or gram-force, to the needle 224 when the wafer 100 is positioned in overdrive 215. In the embodiment illustrated, the spring 222 comprises a beam spring 222a (shown in FIG. 7A). In another embodiment, the spring 222 comprises a C-shaped in-line spring 222b (shown in FIG. 7B). In yet another embodiment, the spring 222c comprises a conductive trace on milar spring mechanism within the base 218 (shown in FIG. 7C). It should be understood that the spring 222 may comprise any suitable device or system for applying a load to the needle 224.

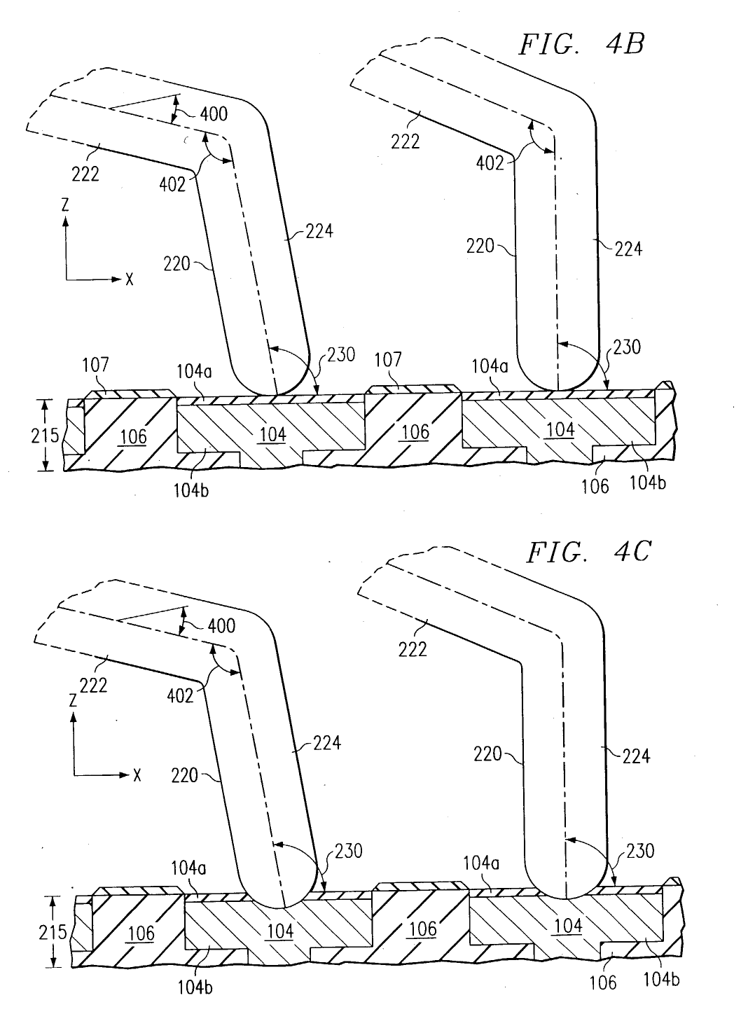

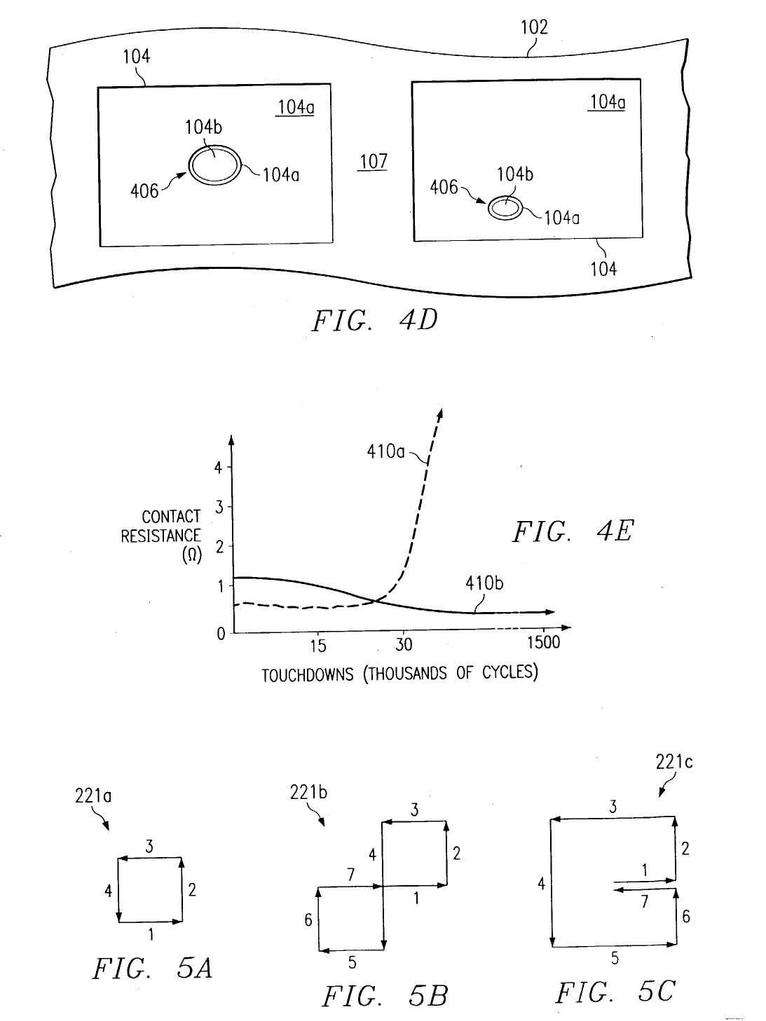

The load produced by the spring 222 is generally dependent upon the amount of overdrive 215, the spring constant of the spring 222, and any offset 228 (shown in FIG. 4A). Offset 228 results from differences in the Z-axis height of the needle 224, as well as variations in the flatness of the wafer 100. As discussed in greater detail below, conventional scrub probes are particularly sensitive to offset 228. In particular, high amounts of offset 228 will prevent a good contact from being made between the bond pad and conventional scrub probes.

The boring action of the bore probe 220 reduces the load required to penetrate the oxide layer 104a of the bond pad 104 as compared to conventional scrub probes. The lower spring constant of the spring 222 improves the ability of the bore probe 220 to compensate for offset as compared to conventional scrub probes. For example, in one embodiment, the spring constant of the spring 222 is one-half the spring constant of a conventional scrub probe. In this embodiment, the variation in the load produced by the spring 222 due to offset is one-half the variation produced in a conventional scrub probe due to the same amount of offset. In a particular embodiment, the spring constant of the spring 222 is 0.02 grams/micron. In addition, conventional scrub probes have a limited Z-axis operating range, whereas bore probes 220 can generally operate over a much larger Z-axis operating range.

The needle 224 is designed to contact the surface of the bond pads 104 at a contact angle 230 that substantially prevents the needle 224 from laterally moving across the surface of the bond pad 104 when the chuck 212 is in overdrive 215. The preferred contact angle 230 is approximately 90° when the wafer 100 is positioned in overdrive 215. This helps prevent the needle 224 from laterally moving across the surface of the bond pad 104 when the wafer 100 is moved in a lateral pattern 232 relative to the bore probe 220. Acceptable results have been obtained with the contact angle 230 at overdrive 215 within a range of 80° to 100°, and preferably within a range of 85° to 95°. It should be understood that although the contact angle 230 has been specified as specific angles and ranges of angles, the contact angle 230 may include other suitable contact angles 230 that substantially prevent the laterally skidding across the bond pad 104 without departing from the scope of the invention.

A contact angle 230 of approximately 90° when the wafer 100 is in overdrive 215 also reduces the effects of offset 228. In contrast, conventional scrub probes are particularly sensitive to offset, as discussed below. Reducing the effects of offset 228 allows the flatness tolerances to be increased for the mounting surface 214, the bore probe card 204, and/or the test head 206. For example, in some embodiments, the length of overdrive 215 can be increased without negatively affecting the boring action of the bore probe 220. Accordingly, the costs associated with the chuck 212, the bore probe card 204, and the test head 206 are reduced as compared to conventional systems.

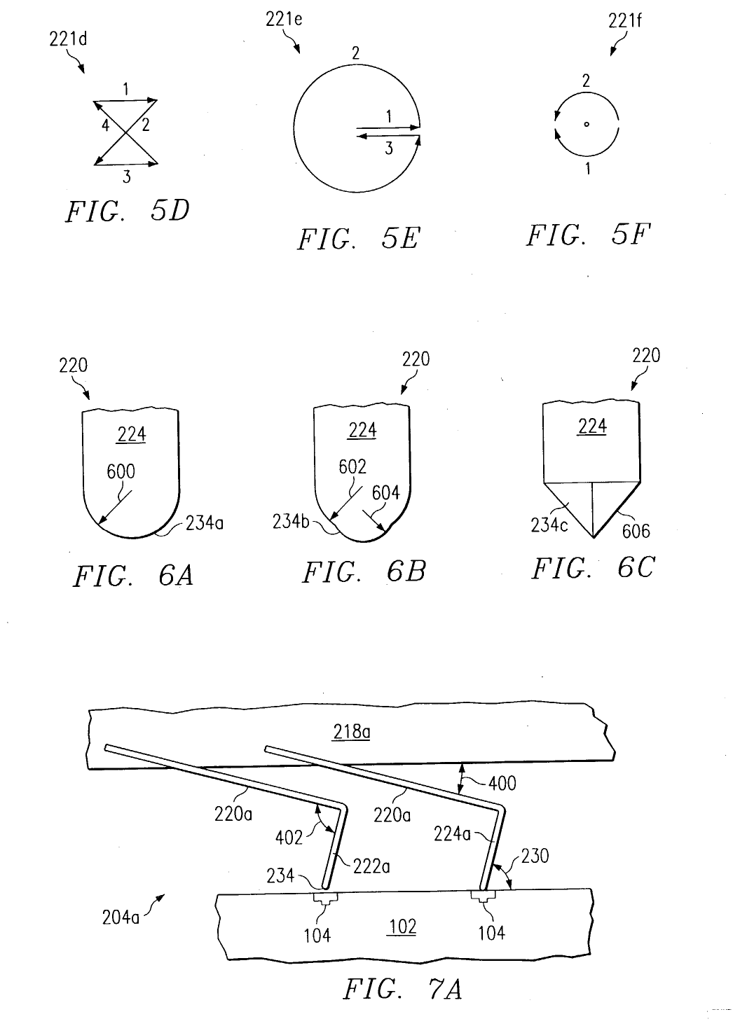

Movement of the bore probe 220 in the lateral pattern 232 (shown in FIGS. 5A-5F) relative to the bond pad 104 allows the bore probe 220 to bore through the oxide layer 104a into the conductive region 104b of the bond pad 104. The area of the bond pad 104 physically contacted by the bore probe 220 is generally less than the area contacted by conventional scrub probes. In particular, the scrubbing requirements of conventional scrub probes require the bond pad 104 to have certain minimum size, which is approximately twice the diameter of the tip of the scrub probe. At the present, conventional scrub probes are limited to a tip diameter on the order of 20 microns or larger.

The needle 224 includes a shaped probe tip 234. The needle 224 is generally tapered down to the shaped probe tip 234. The shaped probe tip 234 operates to penetrate through the oxide layer 104a of the bond pad 104 using the boring action produced by the lateral pattern 232. The shaped probe tip 234 may comprise any suitable shape for facilitating the boring action of the bore probe 220. Examples of different shapes of the shaped probe tip 234 are illustrated in FIGS. 6A-6C. In the embodiment illustrated, the shaped probe tip 234 comprises a radiused probe tip 234a (FIG. 6A). In embodiments for testing bond pads 104 having a size 108 (length 108a and/or width 108b) less than 50 microns, the diameter of the needle 224 is generally on the order of 30 microns or less.

In some embodiments, the boring action of the bore probe 220 helps limit the penetration depth of the needle 224. In particular, experimental tests have shown that the rate of penetration decreases as the needle 224 penetrates into the bond pad 104. Accordingly, the bore probe 220 can be designed such that the penetration of the shaped probe tip 234 into the bond pad 104 substantially stops after penetrating through the oxide layer 104a. The principle factors affecting the penetration depth include the shape of the shaped probe tip 234, the load applied by the spring 222, and the lateral pattern 232. In one embodiment, the shaped probe tip 234 is designed to limit the penetration depth of the shaped probe tip 234. An example of this type of shaped probe tip 234 is a compound probe tip 234b (FIG. 6B). In another embodiment, the penetration depth of the shaped probe tip 234 is controlled by the load applied by the spring 222.

The boring action of the bore probe 220 reduces oxide contamination of the shaped probe tip 234 when penetrating the oxide layer 104a of the bond pad 104. In general, each time the shaped probe tip 234 penetrates the oxide layer 104a, the abrasive oxide polishes the shaped probe tip 234. In other words, the shaped probe tip 234 is self-cleaning. Accordingly, bore probe cards 204 do not require repair and maintenance as often as conventional probe cards. In particular, conventional scrub probes require repair and maintenance due oxide contamination of the contact surface. The difference in contact resistance as a function of touchdowns for conventional scrub probes and the bore probes 220 is illustrated in FIG. 4D.

The bore probes 220 may be fabricated from conventional conductive materials, such as tungsten, rhenium tungsten, beryllium copper, palladium, and the like. As described in greater detail below, conventional scrub probes require high strength materials in order to obtain the high spring rates required to scrub through the oxide layer 104a. In contrast, the boring action of the bore probes 220 reduces the gram-force requirements for the bore probe 220 to penetrate the oxide layer 104a, and therefore the required spring rate of the bore probe 220. As a result, the bore probes 220 can be fabricated from lower strength materials, such as nickel and copper, that are more resistant to contamination and have a lower contact resistance. In particular, a bore probe 220 fabricated from nickel will have a contact resistance that is a fraction of 1 Ohm, and have excellent wear resistance.

The test head 206 operates as a standardized socket for securing and electrically connecting the bore probe card 204 to the tester 208. The test head 206 includes electrical connections (not expressly shown) and a support (not expressly shown). The electrical connections operate to electrically connect the bore probe card 204 to the tester 208, as well as providing a system ground. The support reacts the load applied to the bore probe card 204 while maintaining the alignment of the bore probe card 204. In one embodiment, the test head 206 includes an isolator (not expressly shown) disposed between the support and the bore probe card 204. In the preferred embodiment, the isolator comprises a non-metallic spacer having tight planar tolerances. The isolator operates to electrically isolate the bore probe card 204 and improves the alignment of the bore probe card 204 over a wide range of temperatures.

The tester 208 operates to apply and measure electrical signals from die 102 via the bore probe card 204 and test head 206. The performance of each die 102 in the wafer 100 is generally bin sorted by grade and for failure. High-grade die 102 command a higher price than lower grade die 102. In general, errors in the testing process, such as high contact resistance, reduce the performance of the die 102 and can cause the die 102 to be rejected. These errors are often referred to as false negative errors because the tester 208 incorrectly determines that the die 102 should be rejected or is of a lower grade than it actually is. In many embodiments of the present invention, false negative errors are substantially reduced. Reducing false negative errors in the testing process improves the yield of acceptable and high performance die 102, thereby improving efficiency and reducing costs.

The tester may also operate to controls the operational aspects of the test apparatus 200. In one embodiment, the tester 208 includes a computer readable storage media 236 operable to store a software control program 238. The control program 238 operates to control the positioning system 210 to move the wafer 100 into and out-of overdrive 215 with the bore probes 220. In addition, the control program 238 controls the positioning system 210 to move the wafer 100 in the specified lateral pattern 232 while the wafer 100 is in overdrive 215. In a particular embodiment, the control program 238 also coordinates the lateral pattern 232 with a variation in the overdrive 215, i.e., load produced by the spring 222. For example, the overdrive 215 may be high before the lateral pattern 232 is performed and then reduced when the lateral pattern 232 is performed. The initial high overdrive 215 operates to seat the shaped probe tip 234 into the bond pad 104 to reduce the possibility of scrubbing at a lower overdrive 215.

The tester 208 can also coordinate functions to improve the electrical connection between bore probes 220 and the die 102. In one embodiment the tester 208 pre-tests the die 102 to determine the potential number of poor electrical connections, i.e., high electrical contact resistance, between the bore probe card 204 and the die 102. Based on the pre-test, the electrical contact conditions between the bore probe card 204 and the wafer 100 may be varied to potentially decrease the number of poor electrical connections. For example, as discussed below, the lateral pattern 232 may be repeated, a different lateral pattern 232 may be performed, or the overdrive 215 is increased and then a lateral pattern 232 is performed. This allows the bore probe 220 to more fully bore through the oxide layer 104a of the bond pad 104 and make good electrical contact with the conductive region 104b. Although the test time is increased, the resulting reduction in false negative errors increases the number of acceptable die 102.

FIG. 2B is a flow diagram illustrating the operation of the test apparatus 200 in accordance with one implementation of the invention. Operation is initiated by loading the wafer 100 into the test apparatus 200, as shown by step 250. The wafer 100 is placed onto the chuck 212. The vacuum system 217 pulls the wafer 100 securely into contact with the mounting surface 214 of the chuck 212. The wafer 100 effectively matches the flatness of the mounting surface 214.

The positioning system 210 aligns the chuck 212 at the proper X-Y coordinates to allow the wafer 100 to properly engage the bore probes 220 of the bore probe card 204, as shown by step 252. In the preferred embodiment, alignment of the wafer 100 is controlled by the control program 238. Alignment becomes increasingly important as the size 108 of bond pads 104 become smaller. As a result, proper alignment often includes several tests to help determine alignment. Conventional systems also include a test for profiling the flatness of the top surface of the wafer 100. This was generally required due to the sensitivity of conventional scrub probes to offset 228, as described in greater detail below. In contrast, bore probes 220 are generally not as sensitive to offset 228 as compared to conventional scrub probes. As a result, the flatness profile test may not be required, thereby saving test time and improving the efficiency of the fabrication and testing process.

The chuck 212 and wafer 100 is then moved in the Z-axis toward the bore probe card 204 until the wafer 100 is in overdrive 215. As discussed above, overdrive 215 refers to the position, or distance, the chuck 212 travels in the Z-axis after the wafer 100 initially contacts the bore probes 220. In other words, overdrive 215 is a measure of the amount of compression, or gram-force load, applied by the bore probes 220 to the wafer 100. When in overdrive 215, the spring 222 compresses to produce the load applied to the shaped probe tip 234. The shaped probe tip 234 of the bore probes 220 contacts the respective bond pads 104 of one or more die 102. In a particular embodiment, the amount of overdrive 215 is varied to produce a high initial load. The high initial load operates to lightly dimple the bond pad 104 to help prevent the shaped probe tip 234 from laterally moving across the bond pad 104.

While the chuck 212 is positioned in overdrive 215, the chuck 212 is moved in a lateral pattern 232 relative to the bore probe card 204, as shown by step 256. Although the chuck 212 generally moves to produce the overdrive 215 and lateral pattern 232, the test head 206 can produce the movement to produce the overdrive 215 and lateral pattern 232. The lateral pattern 232 causes the shaped probe tip 234 to penetrate the oxide layer 104a into the conductive region 104b of the bond pad 104 without scrubbing laterally across the bond pad 104. The lateral pattern 234 appears to produce a small relative rotational motion that produces the boring action of the bore probe 220. In some embodiments, the overdrive 215 is varied with the lateral pattern 234. The operation of the bore probe 220 is more fully explained in FIGS. 4A-4C, and the lateral pattern 234 is more fully explained in FIGS. 5A-5F.

The tester 208 then applies and receives electronic test signals to and from the die 102 via the bore probes 220 of the bore probe card 204, as shown by step 258. The particular test procedure varies depending upon the die 102 tested. For example, the test procedure applied to memory chips is substantially different than the test procedure applied to microprocessors. Likewise the time required to complete the test procedure varies. For example, the test procedure for complex microprocessor die 102 is relatively long as compared to the test procedure for simple memory die 102. The tester 208 performance tests the die 102 and sorts the die 102 accordingly.

Upon completing the test procedure, the chuck 212 disengages the wafer 100 from the bore probe card 204, as shown by step 260. The tester 208 determines if all the die 102 in the wafer 100 have been tested, as shown by step 262. If all the die 102 in the wafer 100 have not been tested, the wafer 100 is then repositioned and steps 252 through 262 are repeated until all the die 102 have been tested. Once all the die 102 in the wafer 100 have been tested, the wafer is removed from the chuck 212, as shown by step 264. The die 102 are then cut from the wafer 100. The die 102 may then be bin sorted based on their performance grade. High-grade die 102 generally command a higher price than low-grade die 102.

An alternative implementation is illustrated by the dotted lines. In this implementation, the wafer 100 is processed in accordance with steps 250-256. Upon completing the lateral pattern 232, the die 102 is pre-tested, as shown by step 280. The pre-test generally comprises a quick check of the contact resistance between the bore probes 220 and the bond pads 104. If the number of bore probes 220 having a high contact resistance is below an established threshold, the pre-test is acceptable, as shown by step 282. The acceptable die 102 are then processed in accordance with steps 258-264. If the pre-test indicates that the number of bore probes 220 having a high resistance is above an established threshold, the boring action is repeated. For example, in one embodiment the overdrive 215 is increased to increase the gram-force of the bore probes 220 on the bond pads 104 during the lateral pattern 232. Increasing the gram-force will generally increase the distance the bore probes 220 will penetrate into the bond pad 104. As a result, the bore probes 220 will more likely penetrate into the conductive region 104b of the bond pad 104 and produce a good electrical contact. In another embodiment, only the lateral pattern 232 is repeated to increase the penetration of the bore probes 220 into the respective bond pads 104. In yet another embodiment, a feedback control system is established whereby the overdrive and/or lateral pattern 232 is repeated until the pre-test is acceptable or the pre-test remains unchanged. In this manner, the number of rejected or performance downgraded die 102 due to false negative errors is minimized.

The test apparatus 200, bore probe card 204, and bore probes 220 each offer many advantages over conventional methods and systems, however, it should be understood that various embodiments may have all, some, or none of these advantages. One advantage is that the bore probe card 204 has a longer operational life than conventional probe cards. For example, one bore probe card 204 has been tested for over 1,000,000 cycles, or touches, without the bore probes 220 showing any indication of wear or contamination. In addition, opposite to conventional probes, the contact resistance of the bore probes 220 decreased as the number of touchdowns increased. The long operational life of the probe card 204 also reduces the downtime associated with the test apparatus 200. For example, most companies maintain multiple conventional test apparatus in order to have at least one conventional test apparatus operational at any one time. This is generally due to the short operational life and repair schedule associated with conventional probe cards. The long operational life of the bore probe card 204 and reduced repair schedule may reduce the number of test apparatus 200 needed by a company to test the wafers 100. As a result, capital expenditures for new equipment are reduced.

Another advantage is that smaller bond pad 104 sizes can be tested. In other words, the pitch between bond pads 104 can be reduced and the size of the die 102 can be correspondingly reduced. As a result, a greater number of die 102 can be fabricated in a single wafer 100. In addition, the smaller size of die 102 improves the speed and operational speed of the die 102. This is particularly important when testing complex die 102, such as system-on-chip and microprocessor devices. For example, in at least one embodiment, the bore probe card 204 tests bond pads 104 having a length 108a and/or width 108b less than 40 microns. In contrast, conventional testing methods cannot accurately test bond pads 104 having a length 108a and/or width 108b less than 40 microns. In addition, die 102 having large size bond pads 104 that are ordinarily tested by other systems because of their longer operational life can now be tested using the test apparatus 200 and the bore probe card 204.

Yet another advantage is that the bore probes 220 generally have a lower probability of producing false negative errors during tests of the die 102. Specifically, the boring action of the bore probe 220 is more repeatable than the scrubbing action of conventional scrub probes, and the contact resistance of bore probes 220 generally improves over the operational life of the probe card 204, as illustrated in FIG. 4E. As a result, efficiency is improved and die fabrication and testing costs are reduced.

Yet another advantage of some embodiments is that the bore probes 220 may be aligned closer together than conventional probes. As a result, the bore probe card 204 can have a larger number and/or greater density of probes as compared to conventional probe cards. Accordingly, the number of bond pads 104 and/or die 102 that can be simultaneously tested is increased and the cost per test further reduced.

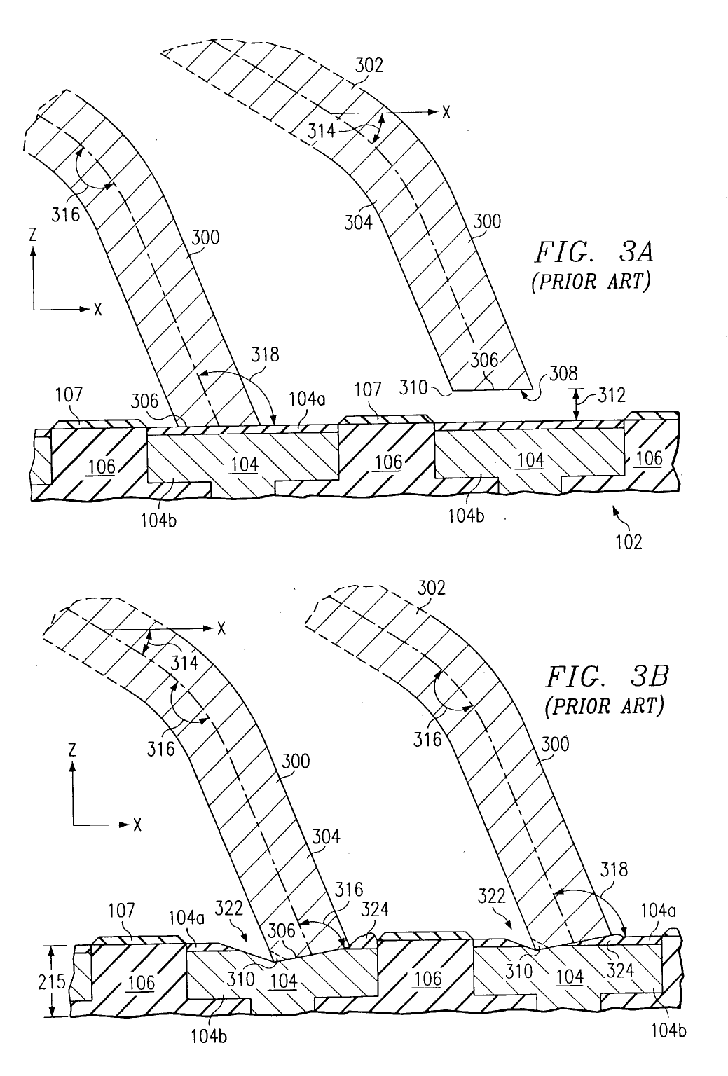

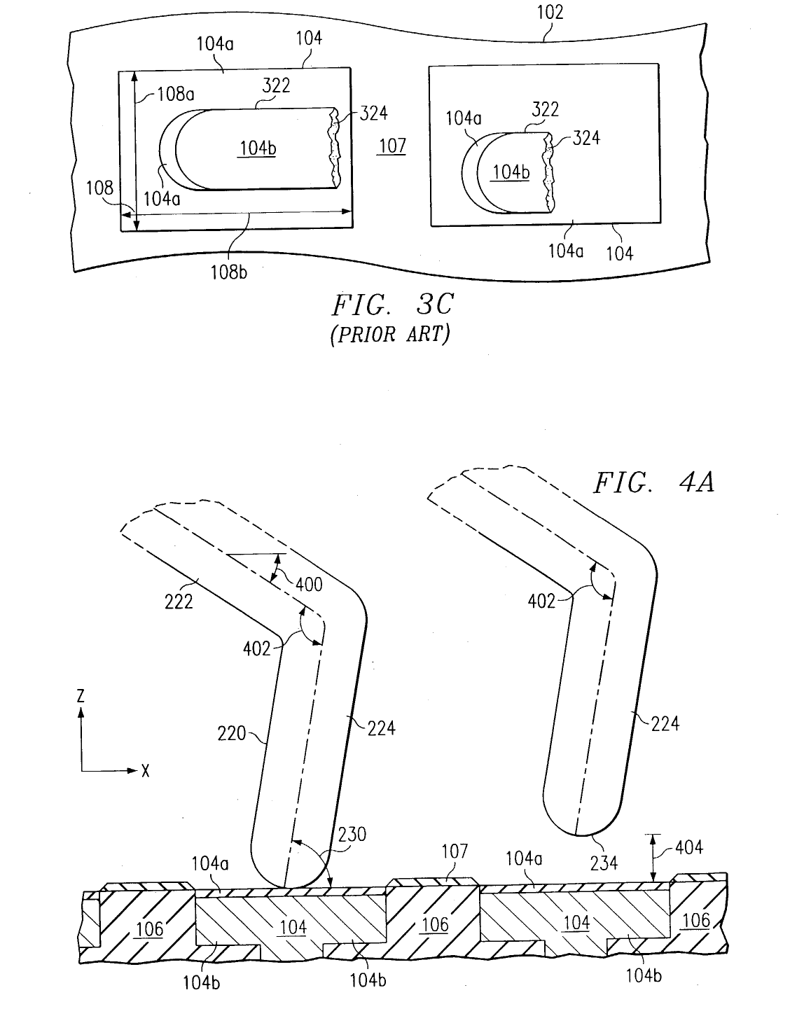

To fully understand the operation and benefits of the bore probe 220, it may be helpful to understand the operation of a conventional scrub probe. Accordingly, FIGS. 3A-3C illustrate the operation of a conventional scrub probe 300, such as used in a conventional scrub probe card (not expressly shown). In particular, FIG. 3A is a side view of scrub probes 300 upon contacting the bond pads 104 of the die 102; FIG. 3B is a side view of the scrubbing action of the scrub probe 300 as the chuck 212 moves the die 102 in the Z-axis by acertain distance of overdrive 215; and FIG. 3C is a top view of the corresponding bond pads 104 shown in FIG. 3B. The operation of the scrub probe 300 is illustrated in terms of the test apparatus 200 and wafer 100.

Each scrub probe 300 includes a spring 302 and a needle 304. The spring 302 operates to apply a load, or gram-force, to the needle 304. Conventional scrub probes 300 have a spring constant on the order of 1 gm/25.4 microns. The needle 304 forms a probe tip 306 generally having a contact surface 308 and a heel 310. During fabrication and when repaired, the probe tip 306 of the scrub probes 300 in the probe card are simultaneously planarized, or polished, to produce the contact surface 308 that is parallel to the surface of the bond pad 104 and having a Z-axis height substantially even the other scrub probes 300. Variations in the Z-axis height of the probe tips 306 between scrub probes 300 and variations in the height of the wafer 100 is referred to as offset 312. As described in greater detail below, offset 312 changes the load applied by the probe tip 306 to the bond pad 104.

Scrub probes 300 rely on certain geometric angles to produce the desired scrubbing action. In particular, scrub probes 300 protrude from a base (not expressly shown) of the probe card at a base angle 314. Scrub probes 300 are bent at a bend angle 316, which allows the needle 304 to contact the bond pad 104 at a contact angle 318. In most conventional scrub probes 300, the base angle 314 is 3° and the bend angle 316 is 105°, which yields 108° for the contact angle 318.

Referring to FIG. 3B, the chuck 212 moves the die 102 in the Z-axis by a certain distance of overdrive 215. The overdrive 215 forces the probe tip 306 of the scrub probe 300 to move laterally across the bond pad 104. The lateral motion of the probe tip 306 pushes the heel 310 through non-conductive region 104a and into the conductive region 104b of the bond pad 104, producing a contact area 322 within the bond pad 104 and debris 324. As described in greater detail below, conventional probes require that the bond pad 104 have a certain minimum size in order for the probe to scrub or otherwise penetrate the oxide layer 104a of the bond pad 104.

The greater the overdrive 215, the greater load applied by the spring 302 and the greater the contact angle 318 and resulting contact area 322. Any offset 312 between individual probe tips 306 results in a corresponding variation in the depth the respective heel 310 penetrates into the bond pad 104 and the contact area 322. If the probe tip 306 scrubs past the bond pad 104, contact occurs between the probe tip 306 and the dielectric material 106 and the passivation layer 107, which results in damage and rejection of the die 102. Accordingly, minimizing the offset 312 is particularly important in conventional scrub probes 300.

Conventional scrub probes 300 have a relatively short operational life before they must be repaired or discarded. One cause is that the oxide layer 104a is hard and abrasive and the scrubbing action wears down the heel 310 of scrub probes 300, as shown by the dotted lines. As the heel 310 becomes worn, the ability of the probe tip 306 to effectively scrub through the oxide layer 104a and make a good electrical contact with the conductive region 104b of the bond pad 104 is degraded. In effect, the probe tip 306 begins to skid across the bond pad 104 without penetrating the oxide layer 104a of the bond pad 104. Conventional scrub probes 300 generally begin to show wear at approximately 15,000 touchdowns, with repair of the scrub probes 300 required at intervals of approximately 30,000 touchdowns. The operational life of conventional scrub probes 300 is generally less than 500,000 touchdowns.

Conventional scrub probes 300 also become contaminated by use. In particular, conventional scrub probes 300 are generally fabricated from tungsten. As the probe tip 306 scrubs through the oxide layer 104a, oxide particles from the oxide layer 104a are impregnated into the contact surface 308 of the probe tip 306. Contamination of the contact surface 308 with the non-conductive oxide increases the electrical resistance of the bore probe 300. Resistance between the probe and the bond pad 104 is generally referred to in the art as contact resistance. Contact resistance is generally measured as a function of the number of touchdowns. FIG. 4E illustrates a graph of the contact resistance as a function of touchdowns for conventional scrub probes 300 and the bore probe 220.

Referring to FIG. 3C, the scrub probe 300 creates the contact area 322 and debris 324 on the bond pad 104. In general, the minimum size 108 of the bond pad 104 is limited by the minimum size of the contact area 322 and alignment tolerances between the scrub probe 300 and the bond pads 104. For example, one conventional scrub probes 300 produces a contact area 322 on the order of the diameter of the probe tip 306 by the lateral scrub of 16.66 microns per 24.4 microns of overdrive 215.

The debris 324 created by the scrubbing action of the scrub probe 300 often results in damaged and rejected die 102. For example, the debris 324 can damage the wafer 100 and die 102 during normal handling and fabrication processes. In addition, the debris 324 often causes problems when the pins 112 (shown in FIG. 1C) are connected to the bond pads 104. A semiconductor device 110 having incomplete bonding between the pin 112 and the bond pad 104 may pass all final tests, but fail when installed into an electrical device 114. As a result, this problem is particularly expensive to correct.

FIGS. 4A-4D illustrate the operation of bore probes 220 in accordance with one embodiment of the invention. Specifically, FIG. 4A is a side view of the bore probes 220 upon initial contact with bond pads 104; FIG. 4B is a side view of the bore probes 220 at overdrive 215; FIG. 4C is a side view of the bore probes 220 after boring through the oxide layer 104a of the bond pad 104; and FIG. 4D is a top view of the contact area in the bond pad 104 resulting from the boring action of the bore probe 220. The operation of the bore probes 220 are described in reference to the test apparatus 200 and a beam spring type bore probe 220a (as shown in FIG. 7A). It should be understood that the present inventions may be used in other suitable systems and test apparatus without departing from the spirit and scope of the inventions.

In the embodiment illustrated, the spring 222 comprises a beam spring 222 that forms a base angle 400 with the X-axis and a bend angle 402 with the needle 224. The base angle 400 provides sufficient room for the bore probe 220 to travel without contacting the base 218 (FIG. 2A). In this embodiment, an initial contact angle 230 is preferably less than 90°, as shown in FIG. 4A. This allows the contact angle 230 to increase to approximately 90° when the wafer 100 is in overdrive 215, as shown in FIG. 4C.

As illustrated in FIG. 4A, the difference between the Z-axis heights of the shaped probe tips 234 and the wafer 100 varies by an amount of offset 404. Offset 404 may be the result of differences between the Z-axis height of the shaped probe tips 234, variations in the Z-axis height, i.e., flatness, of the wafer 100 and chuck 212, parallelism variations in the test head 206, and the like. As illustrated in FIG. 4B, offset 404 varies the contact angle 230, resulting in a variation in the load produced by compression of the spring 222. The bore probes 220 compensate for the offset 404. In particular, the bore probes 220 can compensate for a greater amount of offset 404 than conventional scrub probes 300 without negatively affecting the boring action of the bore probe 220. Combined with a reduced load and/or spring constant for the spring 222, the bore probes 220 can operate over a larger Z-axis distance than conventional probes.

As illustrated in FIG. 4C, the wafer 100 moves in the lateral pattern 232 relative to the bore card 204 (FIG. 2A). The lateral pattern 232 appears to produce a relative circular motion between the shaped probe tip 234 and the bond pad 104. The relative circular motion produces the boring action that allows the shaped probe tip 234, or needle 224, to bore through the oxide layer 104a of bond pad 104. Any suitable lateral pattern 232 may be employed. Examples of the lateral patterns 232 are illustrated in FIGS. 5A-5F.

As illustrated in FIG. 4D, the boring action of the bore probe 220 produces a contact area 406 in the bond pad 104. The contact area 406 is generally circular and approximately the same size or smaller than the shaped probe tip 234. For example, in an embodiment comprising a radiused probe tip 234a (FIG. 6A) having a radius 600 (FIG. 6A) of 3 microns, the load is 0.039 grams/micron, and the lateral pattern 232 is a rectangular quadrant lateral pattern 232a (FIG. 5A) of one micron by one micron, the penetration depth of the radiused probe tip 234a was measured to be 0.6 microns. As illustrated, the contact area 406 includes the area where the bore probe 220 bored through the oxide layer 104a into the conductive region 104b.

The smaller the size of the shaped probe tip 234, the smaller the resulting contact area 406 as compared to conventional probes. In theory, the size 108 of the bond pad 104 could be the same as the contact area 406. However, in practice, the bond pad 104 is sized to allow for a certain amount of tolerance in the XY location where the shaped probe tip 234 contacts the bond pad 104. The tighter the locating tolerance, the smaller the size 108 the bond pad 104 can be fabricated. As described in greater detail below, some embodiments of the bore probes 220 allow the bore probes 220 to be fabricated with tighter locating tolerances than conventional probes. As a result, the length 108a and width 108b of the bond pads 104 can be reduced.

The boring action of the bore probes 220 also does not generally produce any debris as compared to debris 324 produced by scrub probe 300 (FIG. 3C). As discussed above, the debris 324 often interferes with the bonding the pins 112 (FIG. 1C) to the bond pads 104 or quality assurance cosmetic fail. Accordingly, in some embodiments, the boring action improves the bonding process of the pins 112 to the bond pads 104. In addition, the contact area 406 may provide a locating feature for bonding the pin 112 to the bond pad 104. Thereby improving reliability of the electronic device 114 (FIG. 1C) and reducing defects and rejections of the semiconductor device 110 (FIG. 1C).

FIG. 4E is a graph comparing the contact resistance of one embodiment of a conventional scrub probe 300 and one embodiment of a bore probe 220 as a function of cycles, or touchdowns. A graph of the contact resistance 410a of the scrub probe 300 (FIG. 3B) is represented as a dotted line, and a graph of the contact resistance 410b of the bore probe 220 (FIG. 4A) is represented as a solid line 410b. The bore probe 220, as used in this test, was fabricated from tungsten. A bore probe 220 fabricated from nickel would have a lower contact resistance than the tungsten bore probe 220.

Contact resistance is generally important to the accuracy of the tester 206 (FIG. 2A). For example, a high contact resistance generally indicates a defect in the die 102. In particular, at contact resistances substantially greater than 1 Ohm, the tester 206 cannot generally test the die 102 with a high degree of accuracy.

As illustrated, the contact resistance 410a of a new or newly repaired conventional scrub probe 300 is approximately 0.7 Ohms and remains relatively constant for the first 20,000 touchdowns and then dramatically increases at approximately 20,000-30,000 touchdowns. The increase is believed to be due to the non-conductive oxide from the oxide layer 104a becoming embedded in the contact surface 308 (FIG. 3A) of the scrub probe 300. The greater the number of touchdowns, the greater the amount of non-conductive oxide embedded in the contact surface 308. At approximately 20,000-30,000 touchdowns, the conductive area of the contact surface 308 is sufficiently reduced by embedded non-conductive oxide that each additional cycle significantly increases the contact resistance 410a.

In contrast, the contact resistance 410b of the bore probe 220 generally decreases as the number of touchdowns increase. This is believed to be due to the polishing affect of the boring action on the shaped probe tip 234. Specifically, the abrasive oxide from the oxide layer 104a polishes the bore probe 220 each time the shaped probe tip 234 penetrates the oxide layer 104a. As a result, the bore probe 220 improves with use. One embodiment of the bore probe card 204 having beam spring type bore probes 220 has been tested for over 1,500,000 touchdowns and the contact resistance decreased from approximately 1 Ohm to 0.7 Ohms. Inspection of the bore probe card 204 at 1,500,000 touchdowns showed that there was no damage to the bore probes 220. Accordingly, bore probe cards 204 and the bore probes 220 generally have a much longer operational life than conventional scrub probes 300. This results in fewer repairs and reduced costs associated with the test apparatus 200 and testing the die 102.

FIGS. 5A-5F illustrate certain examples of the lateral pattern 232 in accordance with the invention. As discussed above, the lateral pattern 232 refers to the motion of the semiconductor die 102 (FIG. 1A) in the X-Y axis relative to the bore probe card 204 (FIG. 2A). Although certain examples of the lateral pattern 232 are illustrated, the lateral pattern 232 may comprise any suitable motion that facilitates the boring action of the bore probe 220 into the bond pad 104, including any suitable pattern in the X-Y axis or in the X-Y-Z axis. In addition, the specific distance of relative motion traveled in each direction of the lateral pattern 232 depends upon the particular application.

In some embodiments, the amount of overdrive 215 is varied before, after, or during the lateral pattern 232. For example, in one embodiment the overdrive 215 is reduced part way through the lateral pattern 232. This could be useful in cases where the thickness 108c (FIG. 1B) of the bond pad 104 is very thin, the reduced overdrive 215 may prevent the bore probe 220 from penetrating the bond pad 104 and damaging the electrical circuits 109 (FIG. 1B) under the bond pad 104. In another embodiment, the overdrive 215 is higher prior to the lateral pattern 232. This allows the bore probe 220 to slightly dimple the bond pad 104 to help the bore probe 220 maintain position during the lateral pattern 232. In yet another embodiment, the overdrive 215 is higher after the lateral pattern 232. This may improve the contact between the bore probe 220 and the bond pad 104 without increasing the penetration depth of the bore probe 220.

In another embodiment, the tester 206 (FIG. 2A) operates to test and verify that the bore probes 220 have a good electrical contact with the conductive region 104b (FIG. 1B) of the bond pads 104. If a good electrical contact is not established, the lateral pattern 232 is repeated, or the overdrive 215 can be increased and the lateral pattern 232 repeated. In another embodiment, the tester 206 monitors the contact resistance between the bore probes 220 and the bond pad 104. The contact resistance drops when the bore probe 220 penetrates the oxide layer 104a and makes good contact with the conductive region 104b of the bond pad 104. In this embodiment, the tester 206 can repeat the lateral pattern 232 and/or overdrive 215 until all or some threshold portion of the bore probes 220 make good electrical contact with the conductive region 104b of the bond pad 104. In this embodiment, the overdrive 215 could be sequentially increased until good electrical contact is made.

FIG. 5A illustrates a rectangular quadrant lateral pattern 232a. In this embodiment, the relative motion between die 102 and the bore probe card 204 substantially forms a rectangle within one quadrant. The rectangular quadrant lateral pattern 232a is shown by movements 1-4, with the first motion is in the positive X-axis direction by a certain unit of distance; the second motion is in the positive Y-axis direction by a unit of distance; the third motion is in the negative X-axis direction by the unit of distance; and the fourth motion is in the negative Y-axis direction until the origin is reached.

FIG. 5B illustrates a multi-quadrant lateral pattern 232b. The multi-quadrant lateral pattern 232b is shown by movements 1-7, with the first motion is in the positive X-axis direction by a certain unit of distance; the second motion is in the positive Y-axis direction by a unit of distance; the third motion is in the negative X-axis direction by the unit of distance; the fourth motion is in the negative Y-axis direction by twice the unit of distance, the fifth motion is in the negative X-axis direction by the unit of distance; the sixth motion is in the positive Y-axis direction by the unit of distance; and the seventh motion is in the positive X-axis direction until the origin is reached.

FIG. 5C illustrates a full-range rectangular lateral pattern 232c. The full-range rectangular lateral pattern 232c is shown by movements 1-7, with the first motion is in the positive X-axis direction by a certain unit of distance; the second motion is in the positive Y-axis direction by a unit of distance; the third motion is in the negative X-axis direction by twice the unit of distance; the fourth motion is in the negative Y-axis direction by twice the unit of distance, the fifth motion is in the positive X-axis direction by twice the unit of distance; the sixth motion is in the positive Y-axis direction by the unit of distance; and the seventh motion is in the negative X-axis direction until the origin is reached.

FIG. 5D illustrates a crossing lateral pattern 232d. The crossing lateral pattern 232d is shown by movements 1-4, with the first motion is in the positive X-axis direction by a certain unit of distance; the second motion is in the negative X-axis and negative Y-axis direction by a certain unit of distance; the third motion is in the positive X-axis direction by the unit of distance; the fourth motion is in the negative X-axis and positive Y-axis direction until the origin is reached.

FIG. 5E illustrates a circular lateral pattern 232e. The circular lateral pattern 232e is shown by movements 1-3, with the first motion is in the positive X-axis direction by a certain unit of distance; the second motion is a circular motion about the origin; and the third motion is in the negative X-axis direction until the origin is reached.

FIG. 5F illustrates a rotational lateral pattern 232f. The rotational lateral pattern 232f is shown by movements 1-2, with the first motion a clockwise rotation and the second motion a counterclockwise rotation back to the origin.

It should be understood that although FIGS. 5A-5F illustrate various examples of the lateral pattern 232 having certain shapes in certain quadrants, the lateral pattern 232 may comprise any suitable shape or combination of shapes in any suitable quadrant. For example, certain lateral patterns 232 are illustrated as having a square shape, but are not required to be square or rectangular.

FIGS. 6A-6C illustrate certain examples of the shaped probe tip 234. In particular, FIG. 6A is a side view of a radiused probe tip 234a; FIG. 6B is a side view of a compound probe tip 234b; and FIG. 6C is a side view of an angled probe tip 234c. It should be understood that the shaped probe tip 234 may comprise any suitable shape for facilitating the boring action of the bore probe 220 without departing from the scope of the invention. The various shapes of the shaped probe tip 234 may be fabricated by chemically etching the needle 224. In particular, the needle 224 is generally chemically etched to produce a taper down to the shaped probe tip 234.

Referring to FIG. 6A, the radiused probe tip 234a forms a radius 600. The radius 600 depends in part upon the diameter of the needle 224. The load and relative motion between the radiused probe tip 234a and the bond pad 104 displaces the material of the bond pad 104. Tests have shown that the penetration depth of the radiused probe tip 234a is self-limiting and depends generally upon the load and radius 600. For example, a load of 0.47 grams applied to a radiused probe tip having a radius 600 of 3 microns produces a penetration depth of 0.4 microns. The radius 600 also controls generally the size of the contact area 406 (FIG. 4D), and thus the minimum size 108 of the bond pad 104. Accordingly, the radius 600 depends upon the length 108a and/or width 108b of the bond pad 104.

Referring to FIG. 6B, the compound probe tip 234b comprises multiple contours. In the embodiment illustrated, the compound probe tip 234b includes a first radius 602 and a second radius 604. In the preferred embodiment, the first radius 602 is larger than the second radius 604. This embodiment may be used to substantially limit the penetration depth of the compound probe tip 234b into the bond pad 104 without regard to the load applied by the spring 222. Specifically, the contour formed by the second radius 604 penetrates through the oxide layer 104a into the conductive region 104b of the bond pad 104. The increased surface area formed by the first radius 602 reduces the penetration rate of the needle 224 when it contacts the surface of the bond pad 104.

Referring to FIG. 6C, the angled probe tip 234c forms a point 606. In one embodiment, the point 606 is formed as a pyramidal point. In this embodiment, the relative rotational movement of the boring action causes the edges of the pyramidal point to bite into the bond pad 104 and shear the edges of contact area 406 (FIG. 4D) like a cutter. This embodiment can be used to penetrate deeply into the bond pad 104 or bore through a relative thick oxide layer 104a. Some embodiments of the angled probe tip 234c will have the disadvantage or producing debris.

FIGS. 7A-7C illustrate certain examples of the bore probe card 204. In particular, FIG. 7A is a side view of a beam spring bore probe card 204a; FIG. 7B is a side view of a linear bore probe card 204b; and FIG. 7C is a side view of a compound bore probe card 204c. It should be understood that although specific examples of the bore probe card 204 are illustrated, the bore probe card 204 may comprise any suitable device or system for boring into the bond pad 104, including the use of other types and configurations of bore probes 220.

Referring to FIG. 7A, the beam spring bore probe card 204a includes a plurality of beam spring bore probes 220a coupled to a base 218a. The beam spring bore probe 220a was used to illustrate the operation of a generic bore probe 220 in FIGS. 4A-4D. Each beam spring bore probe 220a includes a beam spring 222a and a needle 224a. The base angle 400 is formed between the beam spring 222a and the base 218a; the bend angle 402 is formed between the beam spring 222a and the needle 224a; and the contact angle 230 is formed between the needle 224a and the contact surface of the bond pad 104. As discussed in FIG. 4A, the contact angle 230 in this embodiment is preferably less than 90°. This allows the contact angle 230 to increase to approximately 90° when in overdrive 215.

The initial base angle 400 is generally within a range of 2° to 8°. The bend angle 402 depends upon the base angle 400 and the contact angle 230 when in overdrive 215 (FIG. 4B). For example, in an embodiment in which the base angle 400 is 3°, the contact angle 230 in overdrive 215 is 91° and varies by 3° in response to overdrive 215, the initial contact angle 230 will be 88° and the initial bend angle 402 is 89°. In another embodiment, the base angle 400 is 80°, the contact angle 230 at overdrive 215 is 91° and the base angle 400 varies by 2° during overdrive 215, the initial bend angle 402 is 169°. It should be understood that the beam spring bore probe 220a may comprise other configurations without departing from the scope of the invention. For example, the beam spring bore probes 220a may not be identical. This would allow the beam spring bore probes 220a to be biased for a particular application. For example, the contact angle 230 on different beam spring bore probes 220a may be varied to allow the beam spring bore probes 220a to contact closely spaced bond pads 104.

Referring to FIG. 7B, the linear bore probe card 204b includes a plurality of linear bore probes 220b secured to a base 218b. Each linear bore probe 220b includes an in-line spring 222b and a needle 224b having a shaped probe tip 234. The in-line spring 222b has a certain shape that compresses in response to the overdrive 215 (FIG. 4C) and allows the needle 224b to maintain the contact angle 230 at approximately 90° over the entire length of overdrive 215. The particular shape of the in-line spring 222b depends upon the specific application. In the embodiment illustrated, the in-line spring 222b comprises a C-shaped spring that compresses in response to overdrive 215 (FIG. 4C). In another embodiment, the in-line spring 222b comprises an S-shaped spring (not expressly shown). In yet another embodiment, the in-line spring 222b comprises a coil-shaped spring (not expressly shown). It should be understood that the in-line spring 222b may comprise any suitable shape without departing from the scope of the invention.

The linear bore probes 220b can generally be spaced closer together than conventional probes. For example, in the embodiment illustrated, the linear bore probes 220b are aligned with the in-line spring 222b having a 180° orientation. This allows the linear bore probes 220b to be spaced immediately adjacent to one another. The in-line spring 222b could also be aligned in other orientations, such as every 30°, 60°, 90°, or 120°. As a result, multiple linear bore probes 220b can be spaced very close together without each linear bore probe 220 interfering with an adjacent linear bore probe 220b. Accordingly, the linear probe card 204b can be constructed to contact bond pads 104 having a small size 108 and a small pitch, i.e., spacing between bond pads 104.

The linear bore probes 220b can generally be more easily aligned than conventional scrub probes. In particular, the overall length and bend angles of conventional scrub probes require a substantial amount of tweaking by hand to obtain proper alignment. Specifically, as the size 108 of the bond pad 104 gets smaller, the difficulty and costs to fabricate a conventional probe card becomes increasingly prohibitive. In contrast, the linear bore probes 220b can be accurately aligned with greater accuracy and less hand alignment. As a result, the linear bore probes 220b can be aligned to contact bond pads 104 having a smaller size 108 than conventional probe cards.

Referring to FIG. 7C, the compound bore probe card 204c includes a plurality of compound bore probes 220c movably coupled to a base 218c. Each compound bore probe 220c includes a needle 224c and a compression spring 222c. The compression spring 222c is incorporated into the base 218c. The needle 224c moves within the base 218c to compress the compression spring 222c in response to overdrive 215 and produce a load on the needle 222c. It should be understood that the compound bore probe card 204c may comprise other suitable devices and systems without departing from the scope of the invention.

In the embodiment illustrated, the needle 224c includes a cap 700 and the shaped probe tip 234. The base 218c includes a guide 702 surrounding the needle 224c to precisely guide and support the needle 224c. In one embodiment, the guide 702 comprises a ceramic material. In this embodiment, the ceramic material is coated onto the needle 224c when the needle 224c is at an elevated temperature. Upon cooling, the metallic needle 224c contracts more than the ceramic material, which creates a precision toleranced guide 702. A return spring 704 operates to return the needle 224c to its rest position. In the preferred embodiment, the compression spring 222c and the return spring 704 comprise an elastomer material, such as rubber, silicon, and the like. A housing 706 encapsulates the compression spring 222c and return spring 704. Each needle 224c moves independently in response to overdrive 215 (FIG. 2A) and any offset 404 (FIG. 4A).

FIG. 8 is a flow diagram illustrating a method for constructing a bore probe card 204 in accordance with one implementation of the present invention. It should be understood that the following method may include additional or suitable equivalent steps without departing from the scope of the invention.

Construction is initiated by collecting the requisite number of unfinished bore probes, as shown by step 800. The unfinished bore probes are aligned and positioned such that the tip of the unfinished bore probe will contact the respective bond pads 104 of the die 102, as shown by step 802. A fixture is generally used to properly align and secure the unfinished bore probes. One embodiment of the present invention allows the fixture to be fabricated using conventional semiconductor fabrication techniques, such as photolithography masking and anisotropic etching. This allows the fixture to be accurately fabricated using the same tolerances used to fabricate the die 102 on the wafer 100. This also reduces the amount of hand tweaking that must be used to align the unfinished bore probes.

The unfinished bore probes are then secured in place, as shown by step 804. In some embodiments, the unfinished bore probes are bonded to the base using a non-conductive bonding agent, such as epoxy. This secures the unfinished bore probes without inducing stresses that would substantially change the alignment of the completed bore probes 220. The unfinished bore probes are then electrically connected to a socket that mates to the test head 206.

The tips of the unfinished bore probes are then planarized by polishing the probe tips, as shown by step 806. Planarizing produces unfinished bore probes having a relatively flat contact surface that are substantially parallel to one another. In one embodiment, the unfinished bore probes are planarized while compressed an amount equivalent to overdrive 215 (FIG. 2A). This may help minimize offset 404 (FIG. 4A) between the bore probes 220.

The tips of the unfinished bore probes are then formed into the shaped probe tip 235 (FIGS. 6A-6C) to produce the bore probes 220, as shown by step 808. In the preferred embodiment, the shaped probe tips 235 are produced by chemically etching each of the unfinished probes. Chemical etching allows relatively complex and precision shapes to be produced. It should be understood that other suitable fabrication techniques may be used to form the shaped probe tip 235 without departing from the scope of the present invention.

Although the present invention and its advantages have been described in detail, it should be understood that various changes, substitutions, and alterations can be made therein without departing from the spirit and scope of the present invention as defined by the appended claims.

What is claimed is:

1. A bore probe card for testing one or more semiconductor die, the bore probe card comprising:
a base; and
a plurality of bore probes coupled to the base, wherein each bore probe operates to bore into a bond pad of the semiconductor die in response to a lateral pattern of the semiconductor die relative to the base.

2. The bore probe card of claim 1, wherein each bore probe includes a radiused probe tip.

3. The bore probe card of claim 1, wherein each bore probe includes a compound probe tip.

4. The bore probe card of claim 1, wherein each bore probe includes an angled probe tip.

5. The bore probe card of claim 1, wherein the base includes a compression spring operable to apply a load to a needle.

6. The bore probe card of claim 5, wherein the base further includes a return spring.

7. The bore probe card of claim 1, wherein each bore probe comprises a spring coupled to a needle.

8. The bore probe card of claim 7, wherein the spring comprise an in-line spring.

9. The bore probe card of claim 8, wherein the in-line spring comprises a C-shaped spring.

10. The bore probe card of claim 8, wherein the in-line spring comprises a coil-shaped spring.

11. The bore probe card of claim 7, wherein the spring comprises a beam spring coupled to the base at a base angle and a needle coupled to the spring at a bend angle.

12. The bore probe card of claim 11, wherein the base angle is within a range of 0 degrees to 10 degrees, and the bend angle is within the range of 75° to 95°.

13. The bore probe card of claim 1, wherein the plurality of bore probes are coupled to the base in a plurality of tiers.

14. A bore probe card comprising:
a base; and
at least one bore probe having a spring and a needle, wherein the needle operates to contact a corresponding bond pad of a semiconductor die at a contact angle between the needle and the surface of the bond pad that substantially prevents the needle from laterally scrubbing across the bond pad.

15. The bore probe card of claim 14, wherein the contact angle is substantially within the range of 85 degrees to 95 degrees when the bore probe initially contacts the bond pad.

16. The bore probe card of claim 14, wherein the contact angle is approximately 90 degrees when the semiconductor die is in an overdrive position.

17. The bore probe card of claim 14, wherein the contact angle is less than 90° prior to contacting the bond pad.

18. The bore probe card of claim 14, wherein the spring has a spring constant of approximately 0.05 grams/micron or less.

19. The bore probe card of claim 14, wherein the needle includes a radiused probe tip having a radius less than 50 microns.

20. The bore probe card of claim 14, wherein the needle comprises a shaped probe tip having a radius less than 20 microns.

21. The bore probe card of claim 14, wherein the needle comprises a compound probe tip.

22. The bore probe card of claim 14, wherein the spring comprises a beam spring.

23. The bore probe card of claim 14, wherein the spring comprises an in-line spring.

24. The bore probe card of claim 14, wherein the spring comprises a compression spring disposed within the base.

25. The bore probe card of claim 14, wherein each bore probe has an operating contact resistance of less than 2 Ohms after 50,000 touchdowns.

26. The bore probe card of claim 14, wherein each bore probe has an operating contact resistance of less than 2 Ohms after 100,000 touchdowns.

27. A bore probe comprising:
a spring; and
a needle having a shaped probe tip operable to bore into a bond pad without laterally scrapping across a bond pad.

28. The bore probe of claim 27, wherein the shaped probe tip comprises a radiused probe tip.

29. The bore probe of claim 28, wherein radiused probe tip has a radius less than 50 microns.

30. The bore probe of claim 27, wherein the shaped probe tip comprises a compound probe tip.

31. The bore probe of claim 27, wherein the shaped probe tip comprises an angled probe tip.

32. The bore probe of claim 27, wherein the spring comprises a beam spring.

33. The bore probe of claim 32, wherein a bend angle is formed between the beam spring and the needle such that the bend angle is within a range of 80° to 100°.

34. The bore probe of claim 33, wherein the bend angle is within a range of 85° to 95°.

35. The bore probe of claim 27, wherein the bore probe is fabricated from a tungsten based material.

36. The bore probe of claim 27, wherein the bore probe is fabricated from a nickel based material.

37. A test apparatus for testing a wafer having a plurality of semiconductor die, the test apparatus comprising:
a bore probe card having a plurality of bore probes operable to contact bond pads of the semiconductor die without substantially scrubbing laterally across the bond pad; and
a wafer handling system operable to move the wafer into overdrive and in a lateral pattern while at least one die is engaged with the bore probe card; and
a tester operable to test the die.

38. The test apparatus of claim 37, wherein the tester also operates to test the electrical contact between the bore probes and the bond pads and moves the wafer in a second lateral pattern while the at least one die engages the bore probes.

39. The test apparatus of claim 37, wherein the amount of overdrive is greater prior to the lateral pattern than during the lateral pattern.

40. The test apparatus of claim 37, wherein the direction of the lateral pattern is alternated.

41. The bore probe card of claim 37, wherein the lateral pattern comprises a rectangular quadrant lateral pattern.

42. The bore probe card of claim 37, wherein the lateral pattern comprises a multi-quadrant lateral pattern.

43. The bore probe card of claim 37, wherein the lateral pattern comprises a rotational lateral pattern.

44. The bore probe card of claim 37, wherein a direction of the lateral pattern is alternated.

45. The test apparatus of claim 37, wherein the bore probe card comprises a compound probe card.

46. The test apparatus of claim 37, wherein the bore probe card comprises a linear probe card.

47. The test apparatus of claim 37, wherein the bore probe card comprises a beam spring probe card.

48. The test apparatus of claim 37, wherein the bore probes have a contact resistance less than 2 Ohms after more than 50,000 touchdowns.

49. The test apparatus of claim 37, wherein the bore probes have a contact resistance less than 2 Ohms after more than 250,000 touchdowns.

50. The test apparatus of claim 37, wherein the bore probes include a shaped probe tip having a radius less than 50 microns.

51. The test apparatus of claim 37, wherein the bond pads have a length or width less than 40 microns.

52. The test apparatus of claim 37, wherein the wafer handling system includes a chuck plate constructed from a ceramic material

53. A method for fabricating a device comprising:
providing a wafer having a plurality of semiconductor die, wherein each semiconductor die includes a plurality of bond pads;
testing each semiconductor die in the wafer using a bore probe card having bore probes that bore into the bond pads of the semiconductor die without substantially scrubbing across the bond pads;
cutting each semiconductor die from the wafer;
bonding a pin to at least one of the bond pads; and
encapsulating the semiconductor die within a protective material.

54. The method of claim 53, wherein the device comprises an integrated circuit chip.

55. The method of claim 54, wherein the integrated circuit chip comprises a memory chip.

56. The method of claim 54, wherein the integrated circuit chip comprises a microprocessor chip.

57. The method of claim 53, further comprising installing the encapsulated die into an electronic system.

58. The method of claim 57, wherein the electronic system comprises a circuit board.

59. The method of claim 57, wherein the electronic system comprises a computer.

60. The method of claim 53, wherein the bond pads have a length or width less than 40 microns.

61. A method of fabricating a bore probe card comprising:
positioning a plurality of bore probes to align with a respective bond pad on a semiconductor die;
securing the position of the plurality of bore probes in a base;
planarizing the plurality of bore probes to produce a planarized probe tip; and
forming a shaped probe tip from the planarized probe tip.

62. The method of claim 61, wherein forming a shaped probe tip from the planarized probe tip comprises chemically etching the planarized probe tip to form a shaped probe tip.

63. The method of claim 61, wherein planarizing the plurality of bore probes is accomplished when the bore probes are compressed in overdrive.

64. The method of claim 61, wherein the shaped probe tip comprises a radiused probe tip.

65. The method of claim 61, wherein the shaped probe tip comprises a compound probe tip.

66. The method of claim 61, wherein each bore probe comprises a linear bore probe.

67. The method of claim 66, wherein each linear bore probe includes a C-shaped in-line spring.

68. The method of claim 61, wherein each bore probe comprises a beam spring bore probe.

69. The method of claim 61, wherein positioning a plurality of bore probes to align with a respective bond pad on a semiconductor die comprises positioning a plurality of bore probes in a fixture to align with a respective bond pad on a semiconductor.
